(19) United States
(12) Patent Application Publication
(10) Pub. No.: US 2014/0069678 A1
(43) Pub. Date: Mar. 13, 2014

(54) CASING

(71) Applicants: INVENTEC (PUDONG) TECHNOLOGY CORPORATION, (US); INVENTEC CORPORATION, Taipei (TW)

(72) Inventor: Chia-Ju Ho, Taipei (TW)

(73) Assignees: INVENTEC CORPORATION, Taipei (TW); INVENTEC (PUDONG) TECHNOLOGY CORPORATION, Shanghai (CN)

(21) Appl. No.: 13/779,304

(22) Filed: Feb. 27, 2013

(30) Foreign Application Priority Data
Sep. 12, 2012 (CN) 201210337194.5

(51) Int. Cl. H05K 5/00

(52) U.S. Cl. CPC H05K 5/0004
USPC 174/50

(57) ABSTRACT

A casing includes a first body, multiple lateral plates and multiple flexible components. The first body includes multiple corners and multiple first sides disposed between any two of the multiple corners adjacent to each other. Each of the multiple lateral plates includes two edges opposite to each other and a second side between the two edges. The two edges of each of the multiple lateral plates are connected to any two of the multiple corners, respectively, such that the multiple lateral plates are disposed and surround the first body. There is a gap between the first side and the second side. The multiple flexible components are disposed in the gap and connected to the first side and the second side.

### CROSS-REFERENCE TO RELATED APPLICATIONS

This non-provisional application claims priority under 35 U.S.C. §119(a) on Patent Application No(s). 201210337194.5 filed in China on Sep. 12, 2012, the entire contents of which are hereby incorporated by reference.

### BACKGROUND OF THE INVENTION

1. Technical Field of the Invention

The disclosure relates to a casing, and more particularly to a casing of an electronic device.

2. Description of the Related Art

In recent years, with the advances in technology, electronic devices, such as laptop computers, mobile phones or personal digital assistants (PDA) are becoming more and more popular, and are developed towards a compact design, so as to provide better convenience.

A casing of a general laptop computer is made of plastic or metal. The casing totally made of metal has a better exterior but is heavier. The casing totally made of plastic is lighter but the texture is not as good as the casing made of metal. Therefore, one of the solutions is to attach a metal case onto a plastic case such that this casing has the advantages of both the metal case and the plastic case.

However, during the manufacturing of the metal case and the plastic case, a size error (namely, deviation) may occur due to the manufacturing condition or material property. When the metal case and the plastic case are assembled together, size errors of the two case may affect the assembling. In other words, the metal case and the plastic case may not be tightly attached to each other because of the size errors such that the exterior of the casing and the size are not qualified for a quality check, and even the stress concentration inside the casing may occur so as to make damage.

### SUMMARY OF THE INVENTION

An embodiment of the disclosure provides a casing comprising a first body, a plurality of lateral plates and a plurality of flexible components. The first body includes a plurality of corners and a plurality of first sides disposed between any two of the plurality of corners adjacent to each other. Each of the plurality of lateral plates includes two edges opposite to each other and a second side between the two edges. The two edges of each of the plurality of lateral plates are connected to any two of the plurality of corners, respectively, such that the plurality of lateral plates are disposed and surround the first body. There is a gap between the first side and the second side. The plurality of flexible components are disposed in the gap and connected to the first side and the second side.

### BRIEF DESCRIPTION OF THE DRAWINGS

The disclosure will become more fully understood from the detailed description given herein below for illustration only, thus does not limit the disclosure, wherein:

FIG. 1 is a casing according to an embodiment of the disclosure;

FIG. 2 is a top view of the casing in FIG. 1;

FIG. 3 is a partial exploded view of the casing in FIG. 1;

FIG. 4 is a partial exploded view of a flexible component of the casing in FIG. 1;

FIG. 5 is a partial exploded view of a flexible component of a casing according to another embodiment of the disclosure; and

FIG. 6 is a partial exploded view of a flexible component of a casing according to yet another embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

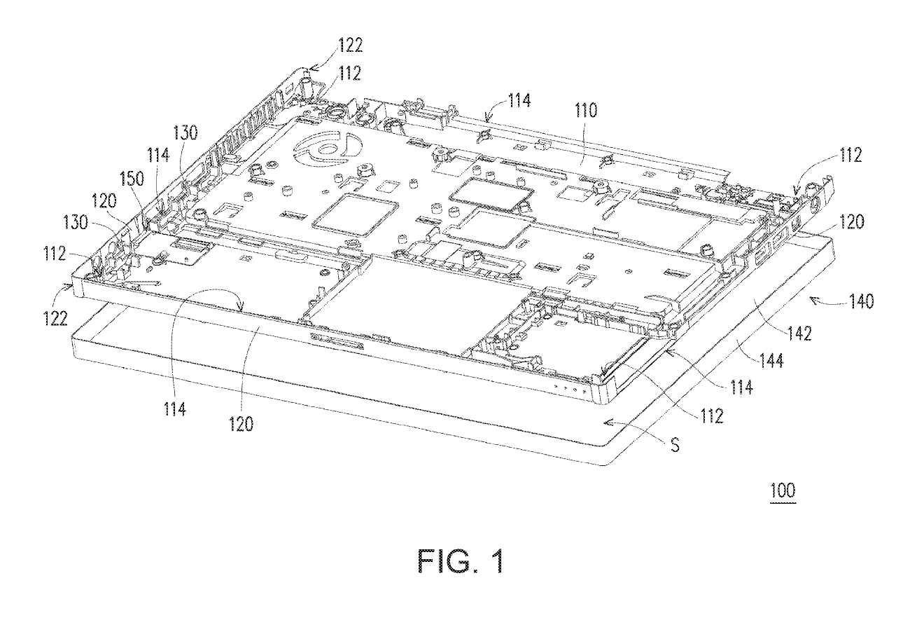

Please refer to FIG. 1, which is a casing according to an embodiment of the disclosure. In this embodiment, a casing 100 is a casing of a laptop computer, but is not limited to the disclosure. The casing 100 comprises a first body 110, a plurality of lateral plates 120, a plurality of flexible component 130 and a second body 140. The second body 140 covers the first body 110 and the lateral plate 120.

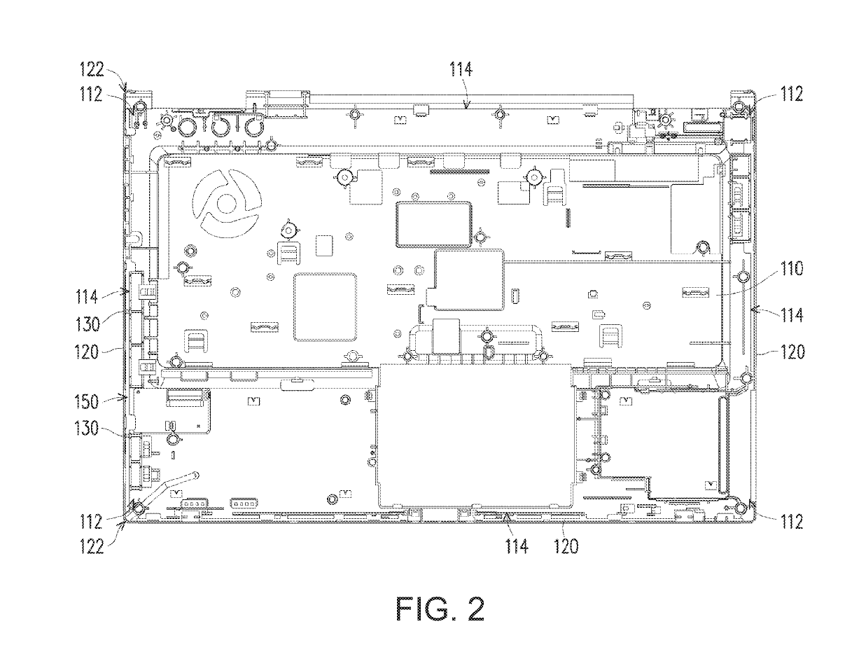

Please refer to FIG. 2, which is a top view of the casing in FIG. 1. In order to make the figures clear, FIG. 2 omits the second body 140. Please refer to FIGS. 1 and 2, the first body 110 includes a plurality of corners 112 and a plurality of first side 114 disposed between any two of the plurality of corners 112. In this embodiment, the first body 110 is a rectangular plate, and therefore the first body 110 includes four corners 112 and four first sides 114, but the shape of the first body 110 and the numbers of the corners 112 and the first sides 114 do not limit the disclosure.

On the other hand, each of the plurality of lateral plates 120 includes two edges 122 opposite to each other and a plurality of second sides 124 between the two edges 122. The two edges 122 of each of the plurality of lateral plates 120 are connected to any two of the plurality of corners 112 of the first body 110 such that the lateral plate 120 is disposed (namely, stood) and surround the first body 110. Therefore, only the two edges 122 of the lateral plate 120 are connected to the first body.

In this embodiment, the casing 100 includes three lateral plates 120, the two edges 122 of each lateral plates 120 are connected to two of the corners 112 adjacent to each other. One of the plurality of edges 122 of each lateral plate 120 is connected to another lateral plate 120. Therefore, each lateral plate 120 is connected to the first body 110 via the two edges 122 to be disposed on the surroundings of the first body 110, and the position where the plurality of lateral plates 120 surround the first body 110 correspond to the three first sides 114 of the first body 110, but the number of the plurality of lateral plates 120 is not limited to the disclosure, and the disclosure does not limit that the lateral plate 120 must connect to other lateral plates 120.

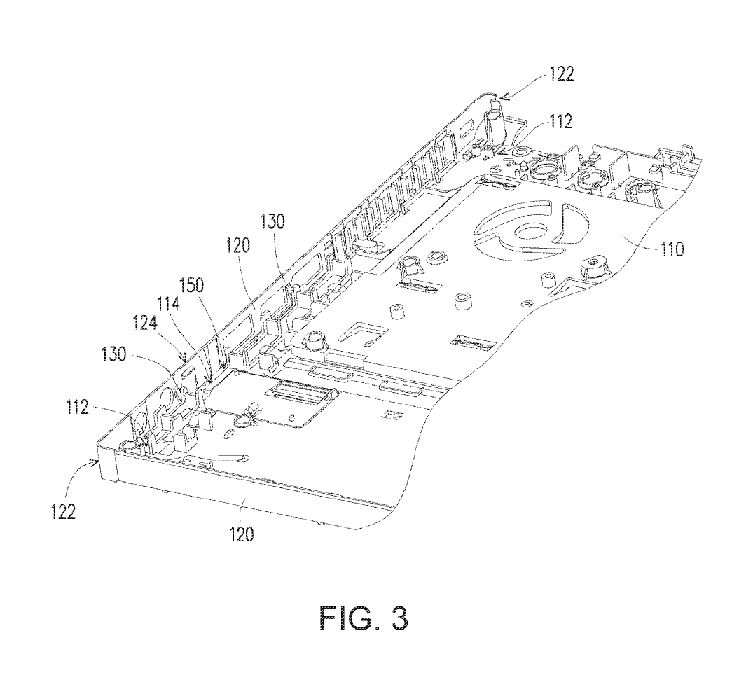

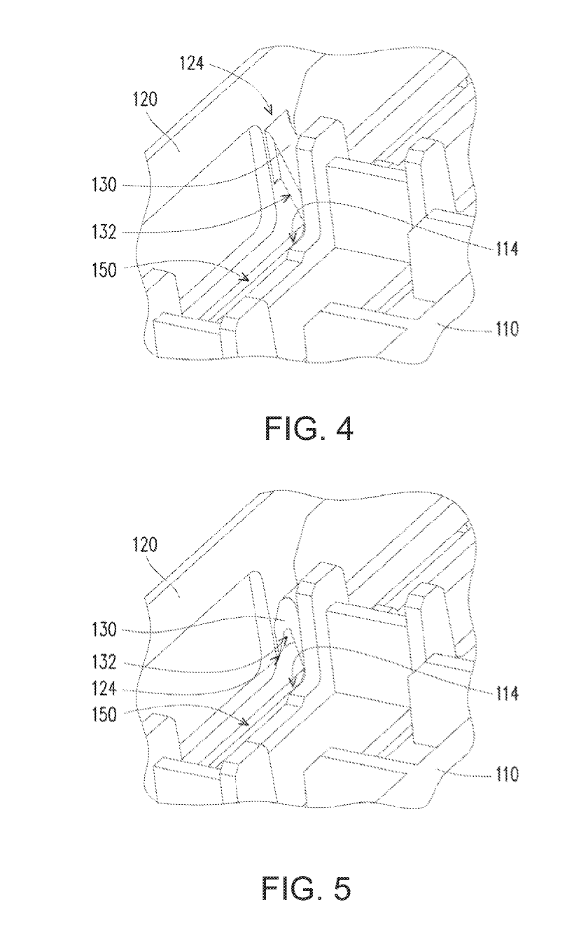

Please refer to FIGS. 3 and 4. FIG. 3 is a partial exploded view of the casing in FIG. 1. FIG. 4 is a partial exploded view of a flexible component of the casing in FIG. 1. In this embodiment, when the two edges 122 of the lateral plate 120 are connected to the two adjacent corners 112 of the first body 110, there is a gap 150 between the first side 114 and the second side 124. Typically, the gap 150 exists between the lateral plate 120 and the first body 110. In this embodiment, the gap 150 is a long and narrow groove, but the shape of the gap 150 is not limited to the disclosure. The gap 150 exists between the first side 114 and the second side 124, and each of the plurality of flexible components 130 is disposed in the gap 150 and is connected to the first side 114 and the second side 124. The flexible component 130 includes at least one bending portion 132 so as to make the flexible component 130 flexible. The number and the position of the flexible component 130 may be adjusted according to actual requirements.

Typically, in this embodiment, the second side 124 is disposed at the upper side of the first side 114, and the flexible component 130 is connected to the first side 114 and the second side 124. In other words, the second side 124 is regarded as the upper end of the lateral plate 120, and the bending portion 132 of the flexible component 130 and the first side 114 are disposed on different planes (i.e., not coplanar with each other), or the bending portion 132 of the flexible component 130 and the second side 124 are disposed on different planes. Therefore, the lateral plate 120 may be pressed against the flexible component 130 such that the lateral plate 120 is moved relative to the first body 110. When the lateral plate 120 is moved relative to the first body 110, the lateral plate 120 is closer to the first body 110 to shorten the width of the gap 150 between the lateral plate 120 and the first body 110.

Please refer to FIG. 5, which is a partial exploded view of a flexible component of a casing according to another embodiment of the disclosure. In this embodiment, the second side 124 and the first side 114 are coplanar with each other. In other words, the second side 124 is regarded as the lower end of the lateral plate 120. Moreover, in this embodiment, the bending portion 132 and the first side 114 are disposed at different planes (i.e., not coplanar) or the bending portion 132 and the second side 124 are disposed at different planes. The flexible component 130 is flexible due to the bending portion 132, and the lateral plate 120 may be moved relative to the first body 110 when the flexible component 130 is pressed towards the first body 110.

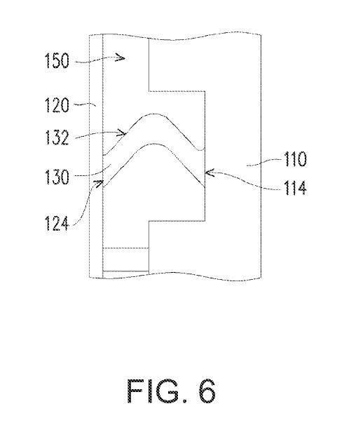

Please refer to FIG. 6, which is a partial exploded view of a flexible component of a casing according to yet another embodiment of the disclosure. In this embodiment, the second side 124 and the first side 114 are disposed at the same plane (i.e., coplanar with each other). In other words, the second side 124 is regarded as a lower end of the lateral plate 120. The bending portion 132 of the flexible component 130, the first side 114 and the second side 124 are disposed at the same plane, that is to say, the bending portion 132 of the flexible component 130 is coplanar with the first side 114 and the second side 124. The bending portion 132 is s-shaped so as to make the flexible component 130 flexible. Therefore, the lateral plate 120 may be moved relative to the first body 110 when the flexible component 130 is pressed toward the first body 110. However, the shape and the position of the flexible component 130 in the above-mentioned embodiments are exemplary, but not limited to the disclosure.

Please refer to FIG. 1 again, in this embodiment, the second body 140 includes a bottom portion 142 and a lateral portion 144, and the bottom portion 142 and the lateral portion 144 form an accommodating space S where the first body 110 and the lateral plate 120 are disposed. When the second body 140 covers and is connected to the first body 110 and the lateral plate 120, the bottom portion 142 abuts against the first body 110, and the lateral portion 144 abuts against each lateral plate 120, such that the first body 110, the lateral plate 120 and the second body 140 are tightly attached to each other.

In this embodiment, the material of the first body 110 is plastic, and the material of the second body 140 is plastic. Furthermore, the material of the lateral plate 120 and that of the flexible component 130 in this embodiment are both plastic. Therefore, the first body 110, the lateral plate 120 and the flexible component 130 are fabricated and integrated into one piece by injection molding at the same time. Because the first body 110, the lateral plate 120 and the second body 140 have different material properties from each other, size errors (namely, deviations) occur during fabricating due to the manufacturing condition or the material property. Therefore, when the first body 110 and the lateral plate 120 are to be assembled into the second body 140 whose material is different from the first body 110 and the lateral plate 120, their size errors may lead to failure of the assembling.

For example, when the sizes of the first body 110 and the lateral plate 120 are greater than a predetermined size due to the error of the fabricating, the sizes of the first body 110 and the lateral plate 120 are greater than that of the second body 140, such that the first body 110 and the lateral plate 120 may not be assembled into the second body 140. However, according to the above-mentioned embodiments, the flexible component 130 and the gap 150 are located between the first body 110 and the lateral plate 120, and the lateral plate 120 is moved relative to the first body 110 when the flexible component 130 is pressed towards the first body 110, such that the lateral plate 120 is closer to the first body 110 to shorten the width of the gap 150 between the lateral plate 120 and the first body 110.

Therefore, when the first body 110 and the lateral plate 120 whose size are slightly greater than usual are assembled into the second body 140, the lateral portion 144 of the second body 140 is pressed against each of the plurality of lateral plate 120, so as to make each lateral plate 120 press against the flexible component 130 having flexibility. The sizes of the first body 110 and the lateral plate 120 is reduced to accommodate to the size of the second body 140 by shortening the width of the gap 150, such that the first body 110 and the lateral plate 120 may be assembled into the second body 140 smoothly. Accordingly, the first body 110 and the lateral plate 120 may be tightly attached to the second body 140 so as to enhance the structural strength of the casing 100.

Moreover, in this embodiment, for example, the first body 110, the lateral plate 120 and the flexible component 130 are fabricated and integrated into one piece by injection molding. Therefore, during the manufacturing process of the first body 110 and the lateral plate 120 by injection molding, the plastic material flows along a channel of a mold which makes the flexible component 130 so as to increase the flowing speed of the plastic material. Therefore, the plastic material may flow to every predetermined position of the mold in a predetermined time, which prevents the first body 110 and the lateral plate 120 from producing burrs and defects, thereby leading to affect the assembling of the casing 100.

Accordingly, the casing 100 provided in this disclosure is regarded as a casing combining with different materials and being applicable for actual requirement. However, the disclosure does not limit the materials of the first body 110 and the second body 140 as well as not limiting that the materials of the first body 110, the lateral plate 120 and the flexible component 130 have to be the same. In addition, in the casing 100, the width of the gap 150 may be adjusted according to possible size errors during actual manufacturing, which makes the casing 100 have better applicability.

To sum up, the casing is provided in the disclosure. There is the gap between the first side of the first body and the second side of each lateral plate, and the flexible component is disposed in the gap and connected to the first side and the second side. When the second body covers the first body and the lateral plate, the second body is pressed against the lateral plate, and the lateral plate is pressed against the flexible component to move relative to the first body, so as to shorten the width of the gap. By means of shortening the width of the gap, the sizes of the first body and the lateral plate accommodate to that of the second body, which makes the first body and the lateral plate assemble into the second body smoothly. Accordingly, the casing has better size applicability.

What is claimed is:

1. A casing, comprising:
a first body including a plurality of corners and a plurality of first sides disposed between any two of the plurality of corners adjacent to each other;
a plurality of lateral plates, each of the plurality of lateral plates including two edges opposite to each other and a second side between the two edges, the two edges of each of the plurality of lateral plates are connected to any two of the plurality of corners, respectively, such that the plurality of lateral plates are disposed and surround the first body, wherein there is a gap between the first side and the second side; and
a plurality of flexible components disposed in the gap and connected to the first side and the second side.

2. The casing according to claim 1, wherein the plurality of flexible components includes at least one bending portion.

3. The casing according to claim 2, wherein the flexible component, the first side and the second side are disposed at a same plane.

4. The casing according to claim 2, wherein the flexible component and the first side are not disposed at a same plane or the flexible component and the second side are not disposed at a same plane.

5. The casing according to claim 1, wherein the second side is at an upper side of the first side.

6. The casing according to claim 1, wherein the gap is a long and narrow groove.

7. The casing according to claim 1, further comprising a second body covering the first body and the plurality of lateral plates.

8. The casing according to claim 7, wherein the material of the first body is plastic, and the material of the second body is metal.
